(19) United States
(12) Patent Application Publication
(10) Pub. No.: US 2023/0383161 A1
(43) Pub. Date: Nov. 30, 2023

(54) HEAT PIPE COOLANT AND FLAT PLATE-LIKE HEAT PIPE

(71) Applicant: Monatec Co., Ltd., Shizuoka (JP)

(72) Inventors: Tooru Nakayama, Shizuoka (JP); Rinkou Fukunaga, Shizuoka (JP)

(21) Appl. No.: 18/031,584

(22) PCT Filed: Sep. 15, 2021
(86) PCT No.: PCT/JP2021/033867

§ 371 Date: Apr. 12, 2023

(30) Foreign Application Priority Data
Oct. 13, 2020 (JP) 2020-172518

(51) Int. Cl. C09K 5/14; F28D 15/02; F28D 15/04; C09K 5/10

(52) U.S. Cl. CPC C09K 5/14; F28D 15/0233; F28D 15/046; C09K 5/10

(57) ABSTRACT

Provided are a heat pipe coolant capable of suppressing deformation of a flat plate-like heat pipe, and a flat plate-like heat pipe. The heat pipe coolant is a coolant enclosed in a flat plate-like heat pipe serving as a heat diffusion plate. The heat pipe coolant includes water and a deformation suppressant that lowers the hardness when the water freezes. The deformation suppressant is 1,4-dioxane or diethylene glycol dimethyl ether. A content of the water is 90 wt % or greater. A content of the deformation suppressant is 0.5 wt % or greater.

### TECHNICAL FIELD

The present disclosure relates to a heat pipe coolant and flat plate-like heat pipe.

### BACKGROUND ART

In heat-generating elements of semiconductor integrated devices (IC), heat pipes are used to suppress malfunctions caused by heat generation. In the related art, heat pipes are disclosed that include a vapor diffusion passage in which a coolant is enclosed in a sealed space under reduced pressure and in which the coolant that has been converted to vapor by the heat from a heat source is diffused, and a capillary channel (wick) that feeds the condensed coolant by capillary action (for example, Patent Literature 1 and 2).

Heat pipes typically are formed from a metal that has high thermal conductivity (for example, copper). In addition to water, which has a high heat of evaporation, ethanol, methanol, acetone, and the like are used as the enclosed coolant.

### CITATION LIST

### Patent Literature

Patent Literature 1: Unexamined Japanese Patent Application Publication No. 2019-113232

Patent Literature 2: Unexamined Japanese Patent Application Publication No. 2009-236362

### SUMMARY OF INVENTION

### Technical Problem

In low temperature environments, the enclosed coolant may freeze. When the coolant freezes, volumetric expansion occurs, which may lead to deformation of the heat pipe.

The present disclosure is made with the view of the above situation, and an objective of the present disclosure is to provide a heat pipe coolant that is capable of suppressing deformation of a flat plate-like heat pipe, and a flat plate-like heat pipe.

### Solution to Problem

A heat pipe coolant according to a first aspect of the present disclosure is a heat pipe coolant enclosed in a flat plate-like heat pipe serving as a heat diffusion plate,
the heat pipe coolant including water and a deformation suppressant that lowers a hardness when the water freezes, wherein
the deformation suppressant is 1,4-dioxane or diethylene glycol dimethyl ether,
a content of the water is 90 wt % or greater, and
a content of the deformation suppressant is 0.5 wt % or greater.

It is preferable that a content of the 1,4-dioxane is from 0.5 to 6.0 wt %.

It is preferable that a content of the diethylene glycol dimethyl ether is from 0.5 to 5.0 wt %.

A flat plate-like heat pipe according to a second aspect of the present disclosure includes:
the heat pipe coolant according to the first aspect of the present disclosure, enclosed in the flat plate-like heat pipe.

The flat plate-like heat pipe may include copper as a main component.

The flat plate-like heat pipe may include a non-metal material as a main component.

The flat plate-like heat pipe may have a laminated structure.

### Advantageous Effects of Invention

According to the present disclosure, a heat pipe coolant capable of suppressing deformation of a flat plate-like heat pipe, and a flat plate-like heat pipe can be provided.

### BRIEF DESCRIPTION OF DRAWINGS

FIG. 1 is a configuration drawing of a device used to measure thermal resistance in the examples; and

FIG. 2 illustrates the structure of a flat plate-like laminated heat pipe fabricated in the embodiment, in which (A), (B), and (C) respectively are photographs illustrating a top plate, a middle plate, and a bottom plate, (D) is a photograph of a state in which a portion of the top plate is removed, and (E) is a cross-sectional view.

### DESCRIPTION OF EMBODIMENTS

### Heat Pipe Coolant

A heat pipe coolant according to the present embodiment is used enclosed in a flat plate-like heat pipe (hereinafter also referred to simply as “heat pipe”) that serves as a heat diffusion plate. The heat pipe coolant evaporates on a heat absorption side of the heat pipe, and the vapor generated thereby moves through a vapor diffusion passage to a heat diffusion side of the heat pipe. On the heat diffusion side, the vapor of the heat pipe coolant is cooled and returns again to a liquid phase state through a capillary channel (a wick). The heat pipe coolant that has returned to a liquid phase again moves to the heat absorption side. Heat moves due to the phase transformation and movement of the heat pipe coolant, and the heat of a heat-generating element in which the heat pipe is provided is dispersed.

The heat pipe coolant includes water and a deformation suppressant. The main component of the heat pipe coolant is the water. Water has a high heat of evaporation and can absorb a large amount of heat and, as such, is useful as a coolant. However, water freezes and volumetrically expands under low temperatures. In particular, a heat diffuser of the heat pipe has a structure in which water is collected due to capillary action. When the heat pipe is placed in a low-temperature environment in a state in which water has accumulated near the heat diffuser, volumetric expansion due to freezing creates a load that acts to cause the wick to expand. The heat pipe may deform due to this load.

The deformation suppressant demonstrates a function of lowering hardness when the water in the heat pipe coolant freezes. The deformation suppressant keeps the water in a so-called sherbet state when the water freezes at low temperatures and, as a result, deformation of the heat pipe is suppressed. Specifically, the deformation suppressant is 1,4-dioxane or diethylene glycol dimethyl ether.

It is preferable that a content of the deformation suppressant in the heat pipe coolant is 0.5 wt % or greater. When the content of the deformation suppressant is insufficient, the deformation suppressing effect decreases. It is thought that the deformation suppressing effect increases as the content of the deformation suppressant increases. However, since the heat of evaporation of the deformation suppressant is lower than that of the water, when the content of the deformation suppressant is excessive, the heat absorption/heat diffusion effects may decrease.

It is preferable that, when the deformation suppressant is the 1,4-dioxane, the content thereof is from 0.5 to 6.0 wt %. It is preferable that, when the deformation suppressant is the diethylene glycol dimethyl ether, the content thereof is from 0.5 to 5.0 wt %. Although it is preferable that the heat pipe coolant includes only the water and the deformation suppressant, trace amounts of other additives may be included.

Additionally, the content of the water is 90 wt % or greater, preferably 94 wt % or greater, and an upper limit of the content of the water is 99.5 wt %.

The 1,4-dioxane and the diethylene glycol dimethyl ether have low reactivity with copper and, as such, can be suitably used in a heat pipe that has copper as the main component.

The 1,4-dioxane and the diethylene glycol dimethyl ether have excellent solubility in water and, as such, disperse evenly in the water to form a homogenous heat pipe coolant. The boiling point of the 1,4-dioxane and the diethylene glycol dimethyl ether is close to that of the water and, as such, the homogeneity of the heat pipe coolant is maintained even during the movement in the channels caused by the evaporation and condensation of the water.

### Flat Plate-Like Heat Pipe

The heat pipe coolant described above is enclosed in a flat plate-like heat pipe. The heat pipe is used attached to a heat source. Examples of the heat source include a semiconductor integrated device (IC), a large scale integrated circuit device (LSI), a central processing unit (CPU), an LED element, a power device, and the like.

Provided that the flat plate-like heat pipe includes an internal space constituted by a vapor diffusion passage in which the vaporized coolant is dispersed and a capillary channel that feeds the condensed coolant by capillary action, and the heat pipe coolant is enclosed in this internal space, the form of the plate-like heat pipe is not limited.

Examples of the form of the plate-like heat pipe include a heat pipe having a laminated structure. Examples of a heat pipe having a laminated structure include the structures disclosed in Japanese Patent No. 5178274 and Unexamined Japanese Patent Application Publication No. 2019-113232. Specifically, these heat pipes are formed by laminating and bonding a top plate, a plurality of middle plates, and a bottom plate, and include an internal space constituted by a vapor diffusion passage and a capillary channel.

The material forming the heat pipe is a material that has high thermal conductivity such as copper, aluminum, and the like, and preferably is copper. The reactivity between the deformation suppressant included in the heat pipe coolant and copper is low and, as such, the heat absorption/heat diffusion effects of the heat pipe are maintained stably over an extended period of time. Note that the material of the heat pipe is not limited to the materials described above, and may be a material that has low thermal conductivity or a non-metal material. Provided that the heat pipe has a configuration such as that disclosed in Japanese Patent No. 5178274, for example, functions as a heat diffusion plate are expected.

### EXAMPLES

As described below, flat plate-like heat pipes in which a variety of coolants are enclosed were fabricated. The fabricated heat pipes were subjected to a heat shock test and a high-temperature storage test by the methods described below. Moreover, thermal resistance immediately after fabrication of the heat pipe, thermal resistance after the heat shock test, thermal resistance after the high-temperature storage test, and appearance after the heat shock test were evaluated using the evaluation methods described below.

### Heat Shock Test

The temperature conditions described below were defined as one cycle, and 1,000 cycles were performed for the heat pipes.

Temperature conditions: −20° C. (30 minutes)→25° C. (10 minutes)→100° C. (30 minutes)→25° C. (10 minutes)

### High-Temperature Storage Test

The heat pipes were stored for 1,000 hours under a temperature condition of 150° C.

### Measurement Method of Thermal Resistance

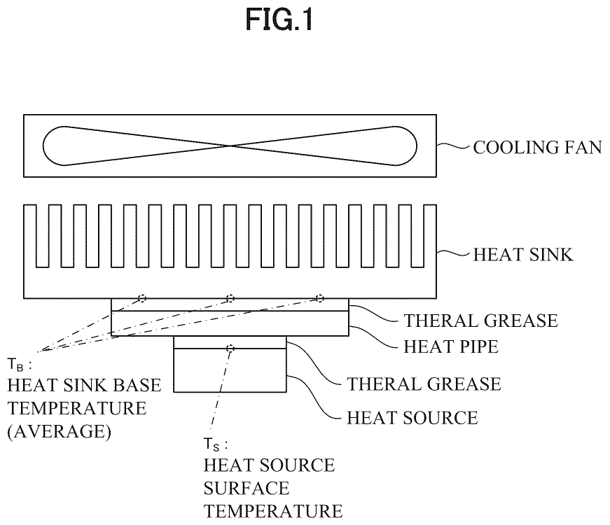

The device configuration illustrated in FIG. 1 was used to measure the thermal resistance. Thermal grease was used, and the heat source, the heat pipe, and a heat sink were sequentially stacked and disposed. Forced air cooling was carried out with a cooling fan.

Voltage was applied to the heat source, and the temperature at which the surface temperature (T_{S}) of the heat source reached a steady state was measured. Additionally, the temperature, in the steady state, at a plurality of locations of the base of the heat sink was measured, and an average temperature (T_{B}) thereof was calculated.

Then, the thermal resistance of the heat pipe was calculated using Equation 1. Note that, in Equation 1, Qin represents an amount of input heat [W].

Thermal resistance (Rth)=(T_{S}−T_{B})/Qin[K/W] (Equation 1)

Additionally, the same measurement as described above was carried out using, instead of the heat pipes, a copper plate having the same size as the heat pipes. Then, the thermal resistance of the copper plate was calculated using Equation 1.

Then, a difference (ΔRth) between the thermal resistance of each heat pipe and the thermal resistance of the copper plate was calculated.

### Evaluation Method of Thermal Resistance Immediately After Fabrication

In the measurement method of the thermal resistance described above, cases in which the difference (ΔRth) between the thermal resistance of the heat pipe and the thermal resistance of the copper plate was 0.06 K/W or greater were evaluated as “GOOD” and cases in which the difference (ΔRth) was less than 0.06 K/W were evaluated as “POOR.”

### Evaluation Method of Thermal Resistance After Heat Shock Test and After High-Temperature Storage Test

In the measurement method of the thermal resistance described above, the difference (ΔRth) between the thermal resistance of the heat pipe after testing and the thermal resistance of the copper plate, and the difference (ΔRth) between the thermal resistance of the heat pipe immediately after fabrication and the thermal resistance of the copper plate were compared. Cases in which a degree of decrease of the ΔRth after testing was less than 0.02 K/W were evaluated as “GOOD”, and cases in which the degree of decrease was 0.02 K/W or greater were evaluated as “POOR.”

### Evaluation Method of Appearance After Heat Shock Test

The appearance of the heat pipes after the test and the appearance of the heat pipes immediately after fabrication were compared, and cases in which a change was not visually recognized were evaluated as “GOOD”, and cases in which a change such as bulging or the like was recognized were evaluated as “POOR.”

### Experiment 1

Coolants obtained by adding each of 1,4-dioxane, diethylene glycol dimethyl ether (hereinafter referred to as “DEGDME”), ethanol, and acetone to pure water, and a coolant including only pure water were prepared.

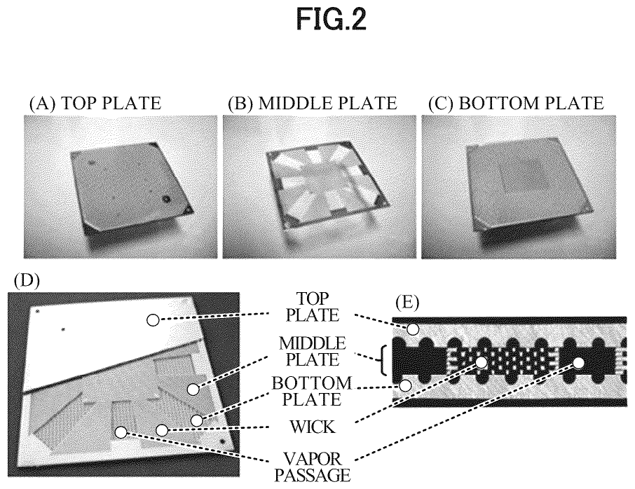

Heat pipes in which these coolants were injected and enclosed were fabricated (Nos. 1 to 5). Note that, in Experiment 1, the structure of the fabricated heat pipes is the structure illustrated in FIG. 2, and conforms to the structure of a commercially available “50 mm square” (50 mm×50 mm, thickness: 2.2 mm) FGHP (registered trademark, Shikoku Instrumentation Co. Ltd.).

The fabricated heat pipes were subjected to the heat shock test and the high-temperature storage test using the methods described above, and the thermal resistance immediately after fabrication of the heat pipe, the thermal resistance after the heat shock test, the thermal resistance after the high-temperature storage, and the appearance after the heat shock test were evaluated. Evaluation results thereof are presented in Table 1.

TABLE 1

| | | | THERMAL | | | THERMAL |
|---|---|---|---|---|---|---|
| | | | RESISTANCE | | THERMAL | RESISTANCE |
| | | ADDED | IMMEDIATELY | APPEARANCE | RESISTANCE | AFTER HIGH |
| | | AMOUNT | AFTER | AFTER HEAT | AFTER HEAT | TEMPERATURE |
| No. | ADDITIVE | (WT %) | FABRICATION | SHOCK TEST | SHOCK TEST | STORAGE TEST |
| 1 | 1,4-DIOXANE | 0.5 | GOOD | GOOD | GOOD | GOOD |
| 2 | DEGDME | 0.5 | GOOD | GOOD | GOOD | GOOD |
| 3 | ETHANOL | 0.5 | GOOD | GOOD | GOOD | POOR |
| 4 | ACETONE | 0.5 | GOOD | POOR | POOR | GOOD |
| 5 | — | — | GOOD | POOR | POOR | GOOD |

The coolants in which the 1,4-dioxane and the DEGDME were added demonstrated good results for all evaluation items. The coolant in which the ethanol was added demonstrated a poor result for the evaluation item of the thermal resistance after high-temperature storage. It is thought that the ethanol reacted with the copper that is the main component of the heat pipe. The coolant in which the acetone was added, and the pure water coolant demonstrated poor results for the evaluation items of the appearance and the thermal resistance after the heat shock test. From the results described above, it is understood that coolants obtained by adding the 1,4-dioxane and the DEGDME to pure water are suitable as coolants for heat pipes.

### Experiment 2

Coolants obtained by adding 3.0 wt %, 1.0 wt %, 0.5 wt %, and 0.1 wt % of the 1,4-dioxane to pure water, and a coolant including only pure water were prepared.

Heat pipes in which these coolants were injected and enclosed were fabricated (Nos. 11 to 15). Note that the structure and size of the heat pipes fabricated in Experiment 2 are the same as those in Experiment 1 described above.

The fabricated heat pipes were subjected to the heat shock test and the high-temperature storage test using the methods described above, and the thermal resistance immediately after fabrication of the heat pipe, the thermal resistance after the heat shock test, the thermal resistance after the high-temperature storage, and the appearance after the heat shock test were evaluated. Evaluation results thereof are presented in Table 2.

TABLE 2

| | | | THERMAL | | | THERMAL |
|---|---|---|---|---|---|---|
| | | | RESISTANCE | | THERMAL | RESISTANCE |
| | | ADDED | IMMEDIATELY | APPEARANCE | RESISTANCE | AFTER HIGH |
| | | AMOUNT | AFTER | AFTER HEAT | AFTER HEAT | TEMPERATURE |
| No. | ADDITIVE | (WT %) | FABRICATION | SHOCK TEST | SHOCK TEST | STORAGE TEST |
| 11 | 1,4-DIOXANE | 3.0 | GOOD | GOOD | GOOD | GOOD |
| 12 | 1,4-DIOXANE | 1.0 | GOOD | GOOD | GOOD | GOOD |
| 13 | 1,4-DIOXANE | 0.5 | GOOD | GOOD | GOOD | GOOD |
| 14 | 1,4-DIOXANE | 0.1 | GOOD | POOR | POOR | GOOD |
| 15 | — | — | GOOD | POOR | POOR | GOOD |

The cases in which the added amount of the 1,4-dioxane was 0.5 wt % or greater demonstrated good results for all evaluation items, but the case in which the added amount of the 1,4-dioxane was 0.1 wt % demonstrated poor results for the appearance and thermal resistance after the heat shock test. Accordingly, it is understood that it is desirable that, when adding the 1,4-dioxane, 0.5 wt % or greater is added.

### Experiment 3

Coolants obtained by adding 6.0 wt %, 4.0 wt %, 2.0 wt %, and 0.1 wt % of the 1,4-dioxane to pure water, and a coolant including only pure water were prepared.

Heat pipes in which these coolants were injected and enclosed were fabricated (Nos. 21 to 25). Note that, in Experiment 3, the structure of the fabricated heat pipes is the structure illustrated in FIG. 2, and conforms to the structure of a commercially available “120 mm round” (diameter: 120 mm, thickness: 2.2 mm) FGHP (registered trademark, Shikoku Instrumentation Co. Ltd.).

The fabricated heat pipes were subjected to the heat shock test and the high-temperature storage test using the methods described above, and the thermal resistance immediately after fabrication of the heat pipe, the thermal resistance after the heat shock test, the thermal resistance after the high-temperature storage, and the appearance after the heat shock test were evaluated. Evaluation results thereof are presented in Table 3.

TABLE 3

| | | | THERMAL | | | THERMAL |
|---|---|---|---|---|---|---|
| | | | RESISTANCE | | THERMAL | RESISTANCE |
| | | ADDED | IMMEDIATELY | APPEARANCE | RESISTANCE | AFTER HIGH |
| | | AMOUNT | AFTER | AFTER HEAT | AFTER HEAT | TEMPERATURE |
| No. | ADDITIVE | (WT %) | FABRICATION | SHOCK TEST | SHOCK TEST | STORAGE TEST |
| 21 | 1,4-DIOXANE | 5.0 | GOOD | GOOD | GOOD | GOOD |
| 22 | 1,4-DIOXANE | 4.0 | GOOD | GOOD | GOOD | GOOD |
| 23 | 1,4-DIOXANE | 2.0 | GOOD | GOOD | GOOD | GOOD |
| 24 | 1,4-DIOXANE | 0.1 | GOOD | POOR | POOR | GOOD |
| 25 | — | — | GOOD | POOR | POOR | GOOD |

As in Experiment 2, the case in which the added amount of the 1,4-dioxane was 0.1 wt % demonstrated poor results for the evaluation items of the appearance and thermal resistance after the heat shock test, and the cases in which the added amount of the 1,4-dioxane was 2.0 wt % or greater demonstrated good results for all of the evaluation items.

### Experiment 4

Coolants obtained by adding 5.0 wt %, 3.0 wt %, and 1.0 wt % of the DEGDME, and a coolant including only pure water were prepared.

Heat pipes in which these coolants were injected and enclosed were fabricated (Nos. 31 to 34). Note that, in Experiment 4, the structure of the fabricated heat pipes is the structure illustrated in FIG. 2, and conforms to the structure of a commercially available “140 mm square” (140 mm×140 mm, thickness: 2.2 mm) FGHP (registered trademark, Shikoku Instrumentation Co. Ltd.).

The fabricated heat pipes were subjected to the heat shock test and the high-temperature storage test using the methods described above, and the thermal resistance immediately after fabrication of the heat pipe, the thermal resistance after the heat shock test, the thermal resistance after the high-temperature storage, and the appearance after the heat shock test were evaluated. Evaluation results thereof are presented in Table 4.

TABLE 4

| | | | THERMAL | | | THERMAL |
|---|---|---|---|---|---|---|
| | | | RESISTANCE | | THERMAL | RESISTANCE |
| | | ADDED | IMMEDIATELY | APPEARANCE | RESISTANCE | AFTER HIGH |
| | | AMOUNT | AFTER | AFTER HEAT | AFTER HEAT | TEMPERATURE |
| No. | ADDITIVE | (WT %) | FABRICATION | SHOCK TEST | SHOCK TEST | STORAGE TEST |
| 31 | DEGDME | 5.0 | GOOD | GOOD | GOOD | GOOD |
| 32 | DEGDME | 3.0 | GOOD | GOOD | GOOD | GOOD |
| 33 | DEGDME | 1.0 | GOOD | GOOD | GOOD | GOOD |
| 34 | — | — | GOOD | POOR | POOR | GOOD |

The coolants in which the DEGDME was added demonstrated good results for all of the evaluation items.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This application claims the benefit of Japanese Patent Application No. 2020-172518, filed on Oct. 13, 2020, the entire disclosure of which is incorporated by reference herein.

1. A flat plate-like heat pipe coolant to be enclosed in a flat plate-like heat pipe, the flat plate-like heat pipe serving as a heat diffusion plate, and having a laminated structure being formed by laminating and bonding a top plate, a plurality of middle plates, and a bottom plate, and including an internal space constituted by a vapor diffusion passage and a capillary channel, the flat plate-like heat pipe coolant comprising:
water; and
a deformation suppressant that lowers a hardness when the water freezes, wherein the deformation suppressant is 1,4-dioxane or diethylene glycol dimethyl ether,
a content of the water is 90 wt % or greater,
a content of the deformation suppressant is 0.5 wt % or greater,
a degree of decrease of a difference between a thermal resistance of the flat plate-like heat pipe after a heat shock test and a thermal resistance of a copper plate from a difference between the thermal resistance of the flat plate-like heat pipe before the heat shock test and the thermal resistance of the copper plate is less than 0.02 K/W, the heat shock test being performed for the flat plate-like heat pipe in which the flat plate-like heat pipe coolant is enclosed, the thermal resistances being measured by a method for measuring a thermal resistance, and
a degree of decrease of a difference between a thermal resistance of the flat plate-like heat pipe after a high-temperature storage test and the thermal resistance of the copper plate from a difference between the thermal resistance of the flat plate-like heat pipe before the high-temperature storage test and the thermal resistance of the copper plate is less than 0.02 K/W, the high-temperature storage test being performed for the flat plate-like heat pipe in which the flat plate-like heat pipe coolant is enclosed, the thermal resistances being measured by the method for measuring the thermal resistance, where
the heat shock test is performed in an order of 30 minutes at −20° C., 10 minutes at 30 minutes at 100° C., and 10 minutes at 25° C. as one cycle, and 1,000 cycles are performed,
the high-temperature storage test is performed by storing the flat plate-like heat pipe for 1,000 hours at 150° C., and
the method for measuring the thermal resistance is performed by (i) stacking and disposing a heat source, the flat plate-like heat pipe or the copper plate, and a heat sink in an order thereof, (ii) measuring a temperature at which a surface temperature of the heat source reached a steady state after applying voltage to the heat source, and then (iii) calculating a thermal resistance of the flat plate-like heat pipe or the copper plate using Equation 1. Thermal resistance (Rth)=(T_{S}−T_{B})/Qin[K/W] (in which Qin represents an amount of input heat [W], T_{S} represents a surface temperature [K] of the heat source, and T_{B} represents an average temperature [K] of temperatures of a plurality of locations of a base of the heat sink reached a steady state).

2. The flat plate-like heat pipe coolant according to claim 1, wherein the content of the 1,4-dioxane is from 0.5 to 6.0 wt %.

3. The flat plate-like heat pipe coolant according to claim 1, wherein the content of the diethylene glycol dimethyl ether is from 0.5 to 5.0 wt %.

4. A flat plate-like heat pipe, comprising:
the flat plate-like heat pipe coolant according to claim 1, enclosed in the flat plate-like heat pipe.

5. The flat plate-like heat pipe according to claim 4, wherein the flat plate-like heat pipe includes copper as a main component.

6. The flat plate-like heat pipe according to claim 4, wherein the flat plate-like heat pipe includes a non-metal material as a main component.

7. The flat plate-like heat pipe according to claim 4, wherein the flat plate-like heat pipe has a laminated structure.
